(19) United States
(12) Patent Application Publication
(10) Pub. No.: US 2010/0141646 A1
(43) Pub. Date: Jun. 10, 2010

(54) ACTIVE MATRIX DISPLAY DEVICE

(75) Inventor: Takahisa Tanabe, Saitama (JP)

Correspondence Address: DRINKER BIDDLE & REATH (DC), 1500 K STREET, N.W., SUITE 1100, WASHINGTON, DC, 20005-1209, US

(73) Assignee: PIONEER CORPORATION, Meguro-ku, Tokyo (JP)

(21) Appl. No.: 12/597,999

(22) PCT Filed: Jul. 23, 2007
(86) PCT No.: PCT/JP2007/064459

§ 371 Date: Oct. 28, 2009

(51) Int. Cl. G06F 3/038; G09G 3/30

(52) U.S. Cl. 345/214; 345/76

(57) ABSTRACT

A display device that includes: first and second drive circuits which are provided in each of the plurality of pixels, and connected to a scanning line and a data line of the display panel, to drive the display element; a scan driver which sequentially scans each scanning line of the display panel; a data driver which supplies the data signal to one of the first and second drive circuits via the data line according to the scanning by the scan driver, and writes the data signal in the one of the first and second drive circuits; and a display controller which drives display elements based on data written in the other one of the drive circuits simultaneously with the data write by the data driver, and executes data display on the display panel.

### TECHNICAL FIELD

The present invention relates to an active matrix display apparatus, and more particularly to an image display apparatus and two-dimensional data display apparatus using an electroluminescent (EL) element.

### BACKGROUND ART

FIG. 1 shows an example of an equivalent circuit of a drive circuit of one pixel PL_{j,i} of an active matrix display device using an organic electroluminescent (OEL) element.

Referring to FIG. 1, the equivalent circuit includes two P-channel TFTs 101 and 102, which are active elements, and a capacitor (Cs) 104. The scanning line Yj is connected to the gate of a selection TFT 101, a data line Xi is connected to the source of the selection TFT 101, and a power supply line Z, to supply a predetermined power supply voltage Vdd, is connected to the source of a drive TFT 102. The drain of the selection TFT 101 is connected to the gate of the drive TFT 102, and the capacitor 104 is formed between the gate and the source of the drive TFT 102. The anode of the OEL 100 is connected to the drain of the drive TFT 102, and the cathode thereof is connected to a ground potential (or common potential).

When a selection pulse is applied to the scanning line Yj, the selection TFT 101 turns on and becomes conducting between the source and the drain. At this time, data voltage is supplied from the data line Xi via the source-drain of the selection TFT 101, and is stored in the capacitor 104. Since the data voltage stored in the capacitor 104 is applied between the gate and the source of the drive TFT 102, the drain current Id according to the gate-source voltage Vgs of the drive TFT 102 flows and is supplied to the OEL 100. The OEL 100 is driven to emit light with light intensity according to the drain current Id.

One drive circuit is normally provided in each pixel PL_{j,i} but a display device and drive method, in which a plurality of drive circuits are provided in each pixel, are disclosed in Japanese Patent Application Laid-Open Kokai No. 2005-331534 and Japanese Patent Application Laid-Open Kokai No. 2006-309155, in order to improve brightness accuracy and low grayscale control.

In the prior art, however, it is important to accurately write brightness data (analog data) in the drive circuit, but increasing the scan count by decreasing the scan period has a limit. Increasing the scan count also decreases the time allocated to the emission period, which decreases brightness and deteriorates the grayscale control.

Recently visible light communication using visible light is developing into practical usage, and the use of a display as a data transmission emission source of the visible light communication is receiving attention. For example, a visible light communication method based on a display using a light emitting diode (LED) has been disclosed. Examples of such communication devices and methods are disclosed in the following Patent Documents 1 to 3.

In the case of the device and method disclosed here, however, 1 bit (or the color signal in each bit) is transmitted simultaneously in the entire display, hence high-speed data transmission is difficult.

A communication method using a plurality of colors of a display has also been disclosed. An example is Japanese Patent Application Laid-open No. 2006-109461. In this system, however, only a maximum of 3 bits can be transmitted simultaneously, so an increase in transmission speed is limited.

Furthermore, a two-dimensional optical communication method using an 8×8 LED (Light Emitting Diode) array, an optical communication method using an LED, which is a backlight light source of the liquid crystal display, and a code pattern for two-dimensional optical communication using a display are disclosed. Examples are Japanese Patent Application Laid-Open Nos. 2006-191313, 2006-319545 and 2007-13786. However no device or method, which can transmit large data volumes at one transmission and which allows high-speed switching of display patterns (two-dimensional transmission data), have been proposed. Therefore high-speed transmission is limited, while higher speed transmission is demanded.

### Patent Document 1: Japanese Patent Application Laid-Open No. 2002-202741

### Patent Document 2: Japanese Patent Application Laid-Open No. 2006-268689

### Patent Document 3: Japanese Patent Application Laid-Open No. 2006-270808

### DISCLOSURE OF THE INVENTION

Examples of problems that the present invention is to solve are the above mentioned shortcomings. It is an object of the present invention to provide an active matrix drive image display device which can perform high brightness and high precision grayscale control. It is another object of the present invention to provide a two-dimensional data display device which allows high-speed transmission.

A display device according to the present invention is a display device that drives, based on data signals, an active matrix display panel in which a display element is provided in each of a plurality of pixels and executes data display, the display device including: a first and second drive circuits that are provided in each of the plurality of pixels, and connected to a scanning line and data line of the display panel, in order to drive the display elements; a scan drive that sequentially scans each scanning line of the display panel; a data driver that supplies the data signals to one of the first and second drive circuits via the data line according to the scanning by the scan driver, and writes the data signals in the one of the first and second drive circuits; and a display controller that drives the display elements based on data written in the other drive circuit simultaneously with the data write by the data driver, and executes data display on the display panel.

### BRIEF DESCRIPTION OF THE DRAWINGS

FIG. 1 is a diagram showing an example of an equivalent circuit of a drive circuit of one pixel PL_{j,i} of an active matrix display device using an organic electroluminescent (OEL) element;

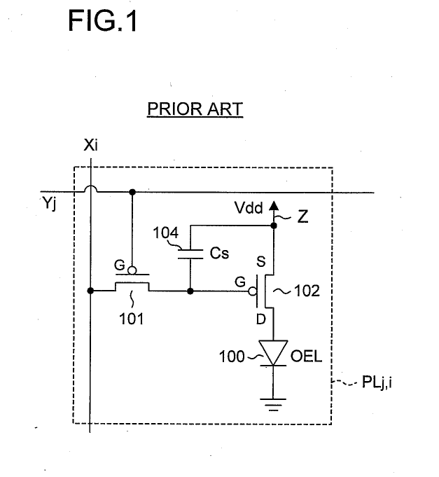

FIG. 2 is a block diagram schematically showing a configuration of the display device using the active matrix display panel according to the present invention;

FIG. 3 is a diagram schematically showing one pixel out of plurality of pixels of the display panel, that is, a pixel PL_{j,i} related to the data line Xi and the scanning line Yj (i,j=1, 2, . . . , n);

FIG. 4 is a diagram schematically showing an example of sub-frames when display driving is executed by a sub-frame method, according to Embodiment 1;

FIG. 5 is a diagram schematically showing an emission drive format according to Embodiment 1. The upper of FIG. 5 shows a drive format of a first drive circuit DC1, and the lower level of FIG. 5 shows a drive format of a second drive circuit DC2;

FIG. 6 is a timing chart showing a state of emission operation or scanning operation by the drive circuits DC1 and DC2, the scan signal and the data signal, when driving is performed based on the drive format shown in FIG. 5;

FIG. 7 is a diagram showing a configuration of a pixel PL_{j,i} when a number of emission selection signal lines is decreased to one according to Embodiment 2;

FIG. 8 is a diagram showing a configuration of a pixel PL_{j,i} when a number of emission selection lines for each pixel is 1, and a number of scanning lines is decreased to one according to Embodiment 3;

FIG. 9 is a diagram showing a configuration of a pixel PL_{j,i} according to Embodiment 4;

FIG. 10 is a diagram showing an example of sub-frames when display driving is performed by the sub-frame method according to Embodiment 4;

FIG. 11 is a diagram showing an example of drive format when three drive circuits DC1, DC2 and DC3 are provided;

FIG. 12 is a block diagram showing a configuration of an image display/data transmission device using an active matrix display panel according to Embodiment 5;

FIG. 13 is a timing chart showing an emission operation and scanning (drive write) operation by the drive circuits DC1 and DC2 according to Embodiment 5;

FIG. 14 is a timing chart showing an emission operation and scanning (data write) operation by the first to third drive circuits DC1, DC2 and DC3 according to Embodiment 6; and

FIG. 15 is a diagram showing a configuration of a pixel PL_{j,i} according to Embodiment 7.

### BEST MODE FOR CARRYING OUT THE INVENTION

Embodiments of the present invention will now be described with reference to the drawings. In the drawings to be described herein below, portions substantially the same are denoted with a same reference symbol.

### Embodiment 1

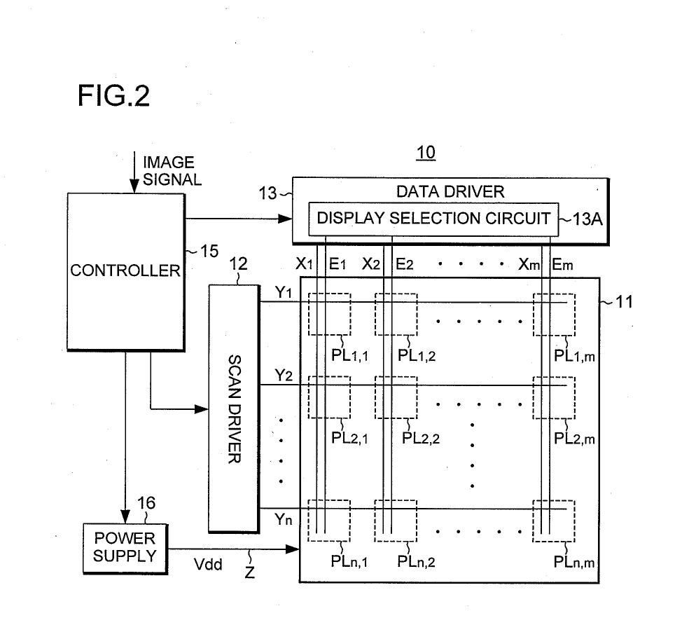

FIG. 2 is a block diagram schematically showing a configuration of a display device 10 using an active matrix display panel according to the present invention. In the present embodiment, the display device 10 is constructed as an image display device which displays supplied image signals.

The display device 10 has a display panel 11, a scan driver 12, a data driver 13, a controller (display controller) 15, and a light emitting element drive power supply (hereafter also called power supply) 16. In the data driver 13, an emission selection circuit (display selection circuit) 13A for selecting the emission driving (display driving) of a plurality of drive circuits which are provided in each pixel, as mentioned later.

A case of using the light emitting element as a display element of the display panel 11 is described herein below, but display control may also be performed by driving a non-light emitting element, such as a liquid crystal display. In the latter case, the light emitting element and emission driving should be regarded as a display element and display driving in the following description.

The display panel 11 is an active matrix type panel comprised of m×n (m and n are two or greater integers) pixels, and has a plurality of parallel data lines X1 to Xm (Xi:i=1 to m) and a plurality of parallel scanning lines Y1 to Yn (or Yj: j=1 to n), and a plurality of pixels PL_{1,1} to PL_{n,m}. The pixels PL_{1,1} to PL_{n,m} are provided at the intersections of the data lines X1 to Xm and scanning lines Y1 to Yn, and all have an identical configuration. A power line Z is connected to each of the pixels PL_{1,1} to PL_{m,n}. A light emitting element (display element) drive voltage (Vdd) is supplied from the power supply 16 to the power line Z.

As mentioned later, each of the scanning lines Yj has a plurality of scan signal lines according to the configuration of the drive circuit provided in the pixel PL_{j,i}. In other words, each of the scanning lines Yj (j=1 to n) has at least one signal line Yj1, Yj2, . . . . In the same way, each of the data lines Xi (i=1 to m) has at least one data signal line X11, Xi2, . . . .

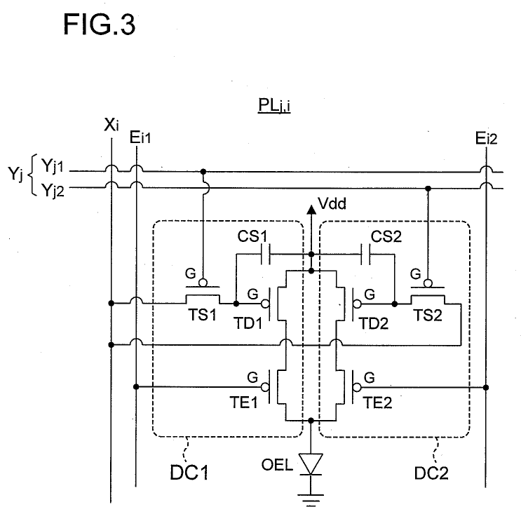

FIG. 3 is a diagram showing one pixel out of a plurality of pixels of the display panel 11, that is, a pixel related to the data line Xi (i=1, 2, . . . , m) and the scanning line Yj (j=1 , 2, . . . , n).

### [Configuration of the Drive Circuit of Pixel and the Driver Circuit]

In a pixel PL_{j,i}, two drive circuits DC1 and DC2 (first and second drive circuits, respectively) and an organic electroluminescent (OEL) element are provided. More specifically, in the drive circuit DC1, a selection transistor TS1, a drive transistor TD1, an emission switching transistor TE1, and a data holding capacitor CS1 are provided. In the drive circuit DC2, a selection transistor TS2, a drive transistor TD2, an emission switching transistor TE2, and a data holding capacitor CS2 are provided.

The case of using the organic electroluminescent (OEL) element for the light emitting element is shown as an example, but the present invention is not limited to this. An inorganic EL light emitting diode, for example, may be used, or a semiconductor (e.g. silicon) based light emitting element may be used. The present invention can also be applied to a liquid crystal display using non-light emitting elements, in the same way.

In the present embodiment, a case of using a P-channel TFT (Thin Film Transistor) for the transistors TS1, TS2, TD1, TD2, TE1 and TE2 is described. The conduction types of transistors are not limited to these, but appropriate types can be selected. Transistors are not limited to organic transistors, but transistors based on amorphous silicon (α-Si) or other semiconductors may be used. Also the transistors are not limited to field effect transistors (FET), but other transistors, such as bipolar transistors, may be used. The polarity and level of the various later mentioned signals and power supply voltages, such as the voltages of the scan signal, the data signal and the selection and switching signal, and the light emitting element drive voltage, can be selected as appropriate according to the material and conduction type of transistors and light emitting elements to be used.

The gate electrode (control electrode) of the selection transistor TS1 of the first drive circuit DC1 is connected to the first scan signal line Yj1 of the scanning line Yj. In the case of the P-channel transistor, the source-drain turns on when a voltage lower than a threshold voltage is applied between the gate and source, and turns off when a voltage higher than the threshold is applied.

The gate electrode (control electrode) of the drive transistor TD1 is connected to the drain (or source) of the selection transistor TS1. The other end (source or drain) of the selection transistor TS1 is connected to the data line Xi. One end of the data holding capacitor CS1 is connected to the gate of the drive transistor TD1, and the other end is connected to the source of the drive transistor TD1 (and the power supply line Z).

The source of the drive transistor TD1 is connected to the power supply line Z, and power supply voltage (positive voltage Vdd) is supplied from the power supply 16. The drive transistor TD1, an emission switching transistor TE1 and an organic EL element (OEL) are connected in series. In other words, the gate of the emission switching transistor TE1 is connected to the emission drive selection line (hereafter called emission selection line) from the display selection circuit (emission selection circuit) 13A. In more detail, the gate of the emission switching transistor TE1 is connected to the first emission selection signal line Ei1 of the emission selection line Ei.

The drain of the drive transistor TD1 is connected to the source of the emission switching transistor TE1, and the drain of the emission switching transistor TE1 is connected to the anode of the organic EL element (OEL). The cathode of the EL element (OEL) 25 is connected to a ground. Therefore when both the drive transistor TD1 and the emission switching transistor TE1 turn ON, the organic EL element (OEL) is driven to emit.

The basic configuration of the second drive circuit DC2 is the same as the first drive circuit DC1, but the gate electrode (control electrode) of the selection transistor TS2 is connected to the second scan signal line Yj2 of the scanning line Yj, and the gate electrode of the emission switching transistor TE2 is connected to the second emission selection signal line Ei2 of the emission selection line Ei. The drive transistor TD2, the emission switching transistor TE2, and the organic El element (OEL) are connected in series, which is the same as the configuration of the first drive circuit DC1. The sources of the drive transistor TD1 of the first drive circuit DC1 and the drive transistor TD2 of the second drive circuit DC2 are connected to each other, and are connected to the power supply line Z. The drains of the emission switching transistor TE1 of the first drive circuit DC1 and the emission switching transistor TE2 of the second drive circuit DC2 are connected to the anode of the organic EL element (OEL). The emission switching transistor TE1 or the emission switching transistor TE2 is turned on according to the applied voltage to the first and second emission selection signal lines Ei1 and Ei2 of the emission selection line Ei, and the organic EL element (OEL) is driven to emit.

The source and drain of each transistor (FET) mentioned above may be reversed and connected. Each transistor of the drive circuits DC1 and DC2 may be constructed by N-channel transistors.

The scanning lines Yj (j=1 to n) of the display panel 11 are connected to the scan driver 12. As mentioned above, each of the scanning lines Yj is composed of a pair of scan signal lines Yj1 and Yj2. The scan signal lines Yj1 and Yj2 are related to the first drive circuit DC1 and the second drive circuit DC2 respectively. The data lines Xi (i=1 to m) are connected to the data driver 13.

The emission selection lines Ei (i=1 to m) of the display panel 11 are connected to the display selection circuit (emission selection circuit) 13A provided in the data drive 13. As mentioned above, each of the emission selection lines Ei is composed of a pair of emission selection signal lines Ei1 and Ei2. The emission selection signal lines Ei1 and Ei2 are related to the first drive circuit DC1 and the second drive circuit DC2 respectively.

### [Operation of Driver Circuit and Drive Circuit]

The scan driver 12 supplies the scan pulses SP to the scanning lines Y1 to Yn according to the scan control signal which is sent from the controller 15 at a predetermined scan timing, so as to sequentially scan the lines.

The data driver 13 supplies pixel data signals for each pixel positioned on the scanning line, to which scan pulses are supplied according to the data control signals transmitted from the controller 15, to the pixels (selected pixels) via the data lines X1 to Xm. The data driver 13 supplies pixel data signals to non-emission pixels in a level at which EL elements do not emit light.

The controller 15 controls the entire display device 10A, that is, controls the scan driver 12, the data driver 13, the display drive selection circuit 13A and the light emitting element drive power supply 16.

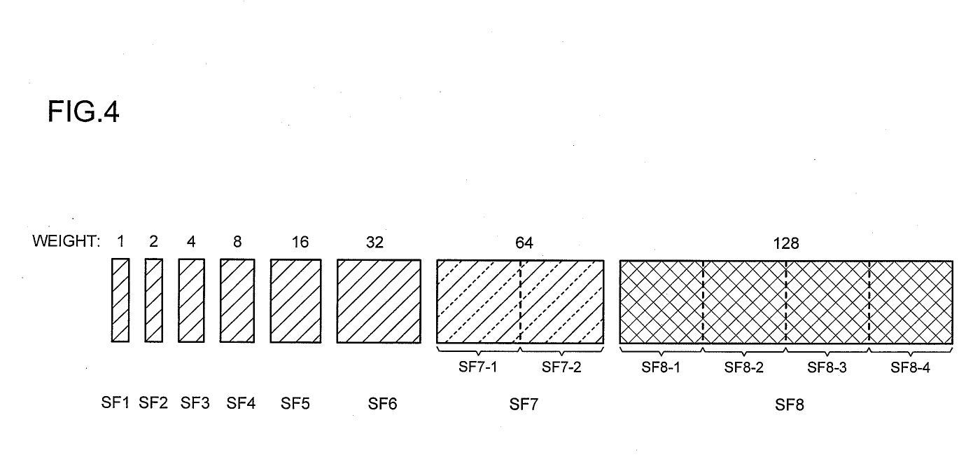

FIG. 4 shows an example of a sub-frame when display drive is performed by a sub-frame method (or sub-field method) according to the present embodiment. In more detail, in this sub-frame method, one frame of an image signal is divided into eight sub-frames (SF1 to SF8), for driving the display of the display panel 11. In other words, each sub-frame is weighted by the emission period. In more concrete terms, the weight of each sub-frame is specified as SFn=2ⁿ⁻1, that is, SF1:SF2:SF3:SF4:SF5:SF6: SF7:SF8=1:2:4:8:16:32:64:128.

In this case, the emission intensity during the emission period is constant, and is in proportion to the duration of the emission period which is determined by the combination of the sub-frames. In other words, brightness data is binary, “1” is (ON) or “0” is (OFF). One frame of the image signal is normally 1/60 of a second (that is, the frame frequency is 60 Hz), but the present invention is not limited to this. By such a combination of sub-frames, 8-bit and 256 grayscale display can be implemented. In the description of the present embodiment, the time required for scanning one screen (all scanning lines) (one screen scan period) is assumed to be about 1/10 of one frame period.

The one screen scan period, number of sub-frames and weighting shown in the present embodiment, however, are merely examples. Appropriate values can be selected or designed according to a desired specification, such as the number of grayscales.

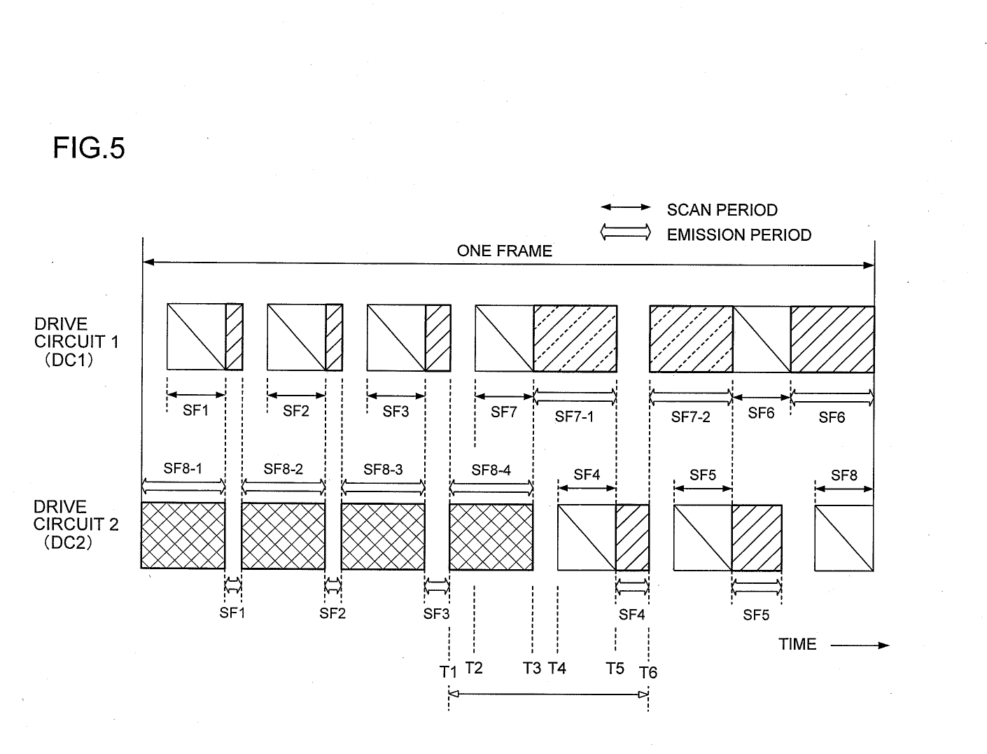

FIG. 5 is a diagram schematically showing an emission drive format according to the present embodiment. The upper level of FIG. 5 shows a drive format of the first drive circuit (drive circuit 1:DC1), and the lower level shows a drive format of the second drive circuit (drive circuit 2:DC2). In other words, driving (scanning, emission) is performed in parallel by the first and second drive circuits DC1 and DC2. This drive operation will be described in detail below.

In the present embodiment, two drive circuits are provided so that while one drive circuit is executing emission drive, the other drive circuit is simultaneously executing the scan of the scanning lines and the data write operation. In addition, a sub-frame having a long sub-frame period is divided, and the timing of the scanning operation and emission operation by the first and second drive circuits DC1 and DC2 are efficiently combined, whereby the emission duty (ratio of the total of emission periods to one frame period) at maximum brightness can be increased (e.g. 90% or more), and an 8-bit and 256 grayscale display can be implemented.

In other words, the controller 15 generates the drive format of the sub-frames and divided sub-frames such that the duty of the total display period by the sub-frames and the divided sub-frames with respect to one frame period become the maximum.

More specifically, the sub-frames SF7 and SF8 (weight is 64 and 128, respectively) are divided into two and four respectively, and the divided sub-frames SF7-1 to SF7-2 and SF8-1 to SF8-4 are set, for example, as shown in FIG. 4. Each of the divided sub-frames SF7-1 to SF7-2 and SF8-1 to SF8-4 has a period corresponding to weight 32, for example.

Specifically, when dividing a sub-frame having a long sub-frame period, it is efficient to divide such that the divided sub-frame period has a time required for the scanning of one screen (all scanning lines) (one screen scan period) or longer. This means that the scan period (data write period) and emission period in the first and second drive circuits DC1 and DC2 can be efficiently executed in parallel by such settings. That is, emission duty, which is a ratio of the total emission period length of each sub-frame and divided sub-frame with respect to one frame period length, can be increased, and high precision multi-grayscale display can be implemented.

In the case of the drive format in FIG. 5, emission driving for the divided sub-frame SF8-1 is executed by the second drive circuit DC2 form the start point of one frame. Note that the scan operation (data write) of the sub-frame SF8 has already been executed in the previous frame of the current frame.

The scan operation (data write) of the sub-frame SF1 is executed in parallel with the emission driving of the divided sub-frame SF8-1 by the first drive circuit DC1. After emission driving of the divided sub-frame SF8-1 ends, the emission driving of the sub-frame SF1 is executed by the first drive circuit DC1. Then the emission driving of the divided sub-frame SF8-2 by the second drive circuit DC2 and the scan operation (data write) of the sub-frame SF2 by the first drive circuit DC1 are executed in parallel. After the emission driving of the divided sub-frame SF8-2 ends, the emission driving of the sub-frame SF2 is executed.

Since the first and second drive circuits DC1 and DC2 are provided as described above, while emission driving is being executed by one drive circuit, scanning lines are scanned and the data write operation is executed simultaneously by the other drive circuit. This aspect will be described in detail with reference to the drawings.

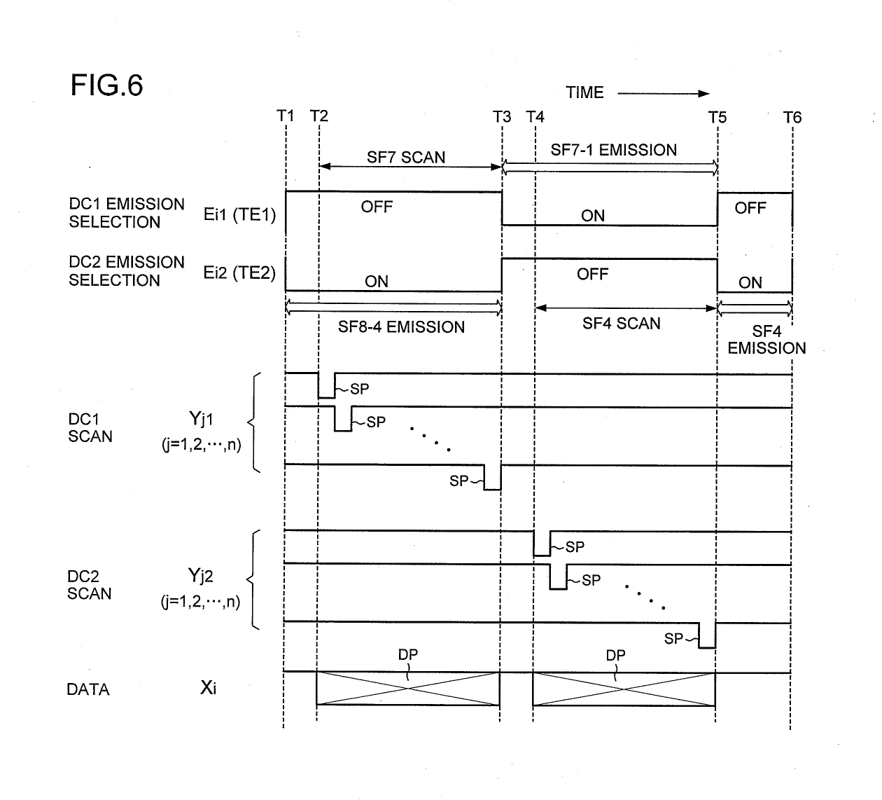

In the drive format in FIG. 5, the emission driving and data write (scan) are executed alternately by the drive circuits DC1 and DC2 from time T1 through T6, for example. FIG. 6 is a timing chart showing the state of the emission operation or scan operation by the drive circuits DC1 and DC2, scan signals and data signals in this case.

At time T1, the selection voltage for emission driving is supplied to the emission selection signal line Ei2, the gate-source voltage of the emission switching transistor TE2 of the second drive circuit DC2 becomes a threshold voltage or less, and the transistor TE2 is turned on. At this time, the scan signal line Yj2 (j=1 to n) of the drive circuit DC2 is maintained in a non-selected state, that is, at a voltage to turn off the selection transistor TS2. Thereby the emission driving of the divided sub-frame SF8-4 is started, and the emission continues until time T3. In the period from time T1 to time T3, on the other hand, voltage which indicates non-emission driving (not selecting emission) is supplied to the emission selection signal line Ei1 to the first drive circuit DC1, and the emission switching transistor TE1 of the drive circuit DC1 is maintained in a turned-off state.

In the period from time T2 to time T3, data write (scan) for a sub-frame SF7 is executed by the first drive circuit DC1 in parallel with the emission driving for the divided sub-frame SF8-4. In more detail, the scan signals SP are sequentially applied to the scan signal lines Yj1 (j=1 to n) of the drive circuit DC1, and sequential line scanning is executed. The scan period (from time T2 to time T3) may be called the address period (Tadr). Then the data signal DP, to indicate the emission brightness for each pixel corresponding to the sequential line scanning, is applied via the data lines X1 to Xm, and data write is executed.

After emission driving of the divided sub-frame SF8-4 ends, the selection voltage signal for emission driving is supplied to the emission selection signal line E11 at time T3, and the emission switching transistor TE1 of the first drive circuit DC1 is turned on. At this time, the scan signal line Yj1 (j=1 to n) of the drive circuit DC1 is maintained in a non-selected state, that is, at a voltage to turn the selection transistor TS1 off. Thereby emission driving of the divided sub-frame SF7-1 is started, and emission continues until time T5. In the period from T3 to time T5, on the other hand, voltage which indicates non-emission driving (not selecting emission) is supplied to the emission selection signal line Ei2 to the second drive circuit DC2, and the emission switching transistor TE2 of the drive circuit DC2 is maintained in the turn-off state.

In the period from time T4 to time T5, data write (scan) for the sub-frame SF4 is executed by the second drive circuit DC2 in parallel with the emission driving for the divided sub-frame SF7-1. In more detail, the scan signals SP are sequentially applied to the scan signal lines Yj2 (j=1 to n) of the drive circuit DC2, and sequential line scanning is executed. Then data signal DP, which indicates the emission brightness for each pixel corresponding to the sequential line scanning, is applied via the data lines X1 to Xm, and data write is executed.

In the period from time T5 to time T6, the first drive circuit DC1 becomes a non-emission state (emission switching transistor TE1 is turned off), the second drive circuit DC2 becomes emission driving state (emission switching transistor TE2 is turned on), and the emission driving of the sub-frame SF4 is executed.

As described above, according to the present embodiment, two drive circuits are provided in each pixel. And while emission driving is being executed by one drive circuit, scanning lines are scanned, and data write operation is executed by the other drive circuit simultaneously.

In the prior art, accurately writing the brightness data (analog data) is important, and therefore increasing the scan count by decreasing the scan period has limitations. Increasing the scan count also decreases the time allocated to the emission period, which causes a drop in brightness and deterioration of grayscale control.

As mentioned above, according to the present embodiment, emission driving and data write can be simultaneously executed in parallel using a plurality of drive circuits, so a scan count that can be executed during one frame period can be increased without sacrificing the duration of the emission period. Also a sub-frame, particularly a sub-frame having a long sub-frame period, is further divided, and periods of the scan operation and emission operation in the first and second drive circuits DC1 and DC2 are efficiently combined, thereby the emission duty (ratio of total emission periods to one frame period) can be increased, and high brightness and high precision grayscale control can be implemented.

In the present embodiment, the transistors used for the drive circuits DC1 and DC2 of the pixel are constructed using transistors having the same polarity (P-channel transistors), therefore another advantage is that the manufacturing steps are easy.

### Embodiment 2

In the above-described embodiment, when providing two drive circuits DC1 and DC2 in a pixel PL_{j,i} and providing two signal lines (Yj1, Yj2) for each scanning line Yj or providing two signal lines (Ei1, Ei2) for each emission selection line Ei was described, but the number of scanning lines and/or emission selection signal lines can be decreased by improving the configuration of the drive circuit.

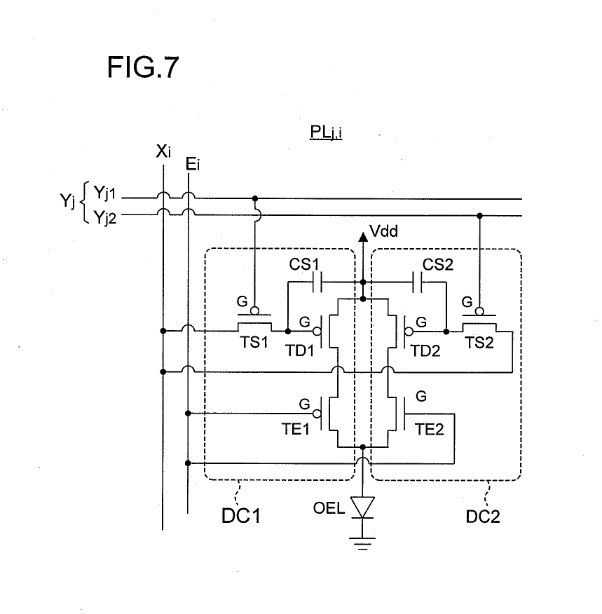

FIG. 7 is a diagram showing a configuration of a pixel PL_{j,i} when the number of emission selection signal lines is decreased to one. As FIG. 7 shows, N-channel transistors are combined with P-channel transistors. More specifically, the emission switching transistor TE2 of one of the drive circuits DC2 is changed to an N-channel transistor, and the gate electrode of the transistor TE2 is connected to one emission selection line Ei. In other words, if one of the emission switching transistors (e.g. P-channel transistor TE1) of the two drive circuits DC1 and DC2 is turned on by applying voltage to the emission selection line Ei, the other emission switching transistor (N-channel transistor TE2) is turned off. If the emission switching transistor TE1 is turned off by applying voltage to the emission selection signal line Ei, on the other hand, the emission switching transistor TE2 is turned on.

Hence, by such a configuration as well, emission driving and data write can be simultaneously executed in parallel by the two drive circuits DC1 and DC2, just like the case of Embodiment 1, and high brightness and high precision grayscale control can be implemented.

### Embodiment 3

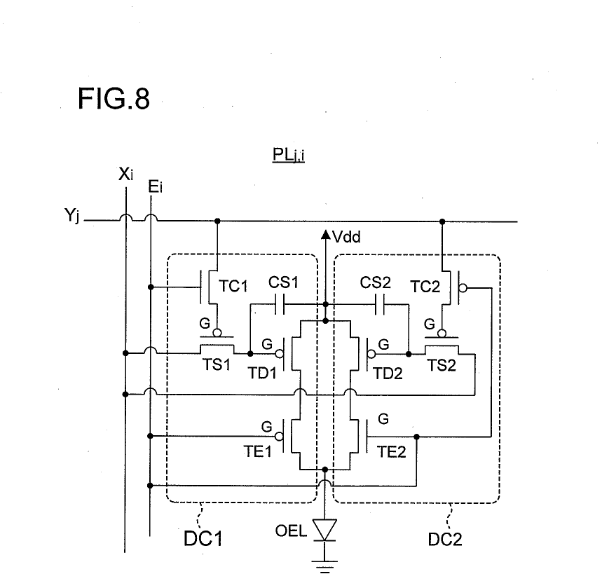

FIG. 8 is a diagram showing a configuration of a pixel PL_{j,i} in the case of decreasing a number of emission selection signal lines in each pixel to one, and a number of scanning lines thereof to one.

As FIG. 8 shows, connection switching transistors TC1 and TC2, to switch the connection to the scanning line Yj, are provided in the first and second drive circuits DC1 and DC2 respectively. More specifically, the transistors TC1 and TC2 are transistors having opposite polarities (N-channel transistor and P-channel transistor respectively), and are connected to the gates of the selection transistors TS1 and TS2.

The gate of the connection switching transistor TC2 of the second drive circuit DC2 is connected to the gate of the emission switching transistor TE2 (and emission selection signal line Ei), and if the emission switching transistor TE2 (N-channel transistor) is turned off, the connection switching transistor TC2 (P-channel transistor) is turned on.

Hence by such a configuration as well, emission driving and data write can be simultaneously executed in parallel by the two drive circuits DC1 and DC2, just like the above embodiments, and an effect equivalent to the above embodiments can be implemented.

### Embodiment 4

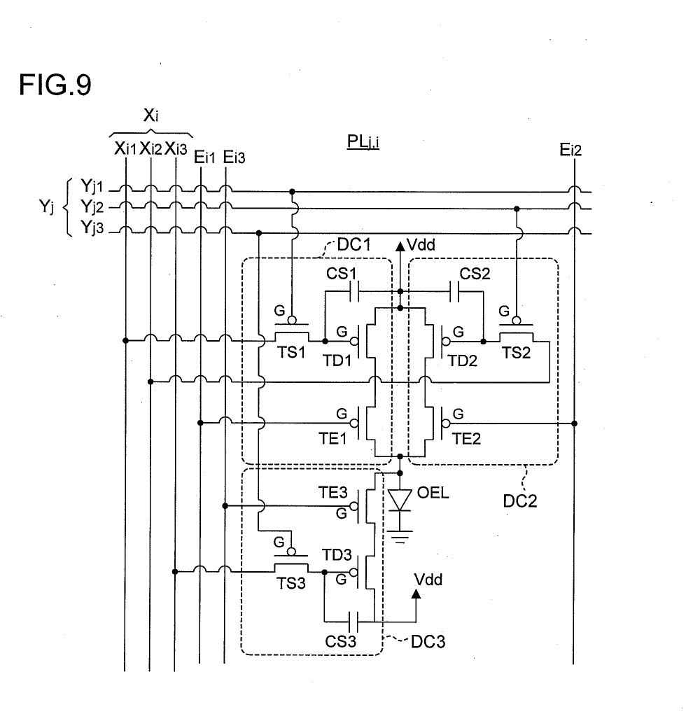

FIG. 9 is a diagram showing a configuration of a pixel PL_{j,i} according to Embodiment 4. In the above embodiments, a case of disposing two drive circuits DC1 and DC2 in a pixel PL_{j,i} is shown, but in the present embodiment, the pixel PL_{j,i} further has a third drive circuit DC3, and is comprised of a total of three drive circuits.

The third drive circuit DC3 has a configuration similar to the drive circuits DC1 and DC2. The third drive circuit DC3 is connected with the drive circuits DC1 and DC2 in parallel. More specifically, the drive circuit DC3 is provided with a selection transistor TS3, a drive transistor TD3, an emission switching transistor TE3, and a data holding capacitor CS3.

In the pixel PL_{j,i}, scanning lines Yj (Yj1, Yj2, Yj3), data lines Xi (Xi1, Xi2, Xi3) and emission selection lines Ei (Ei1, Ei2, Ei3) are provided, and are connected to the gate of the selection transistors TSk, the source (or drain) of the selection transistor TSk and the gate of the emission switching transistor TEk respectively (k=1, 2, 3). Each drive circuit DC1, DC2 and DC3 can be independently controlled.

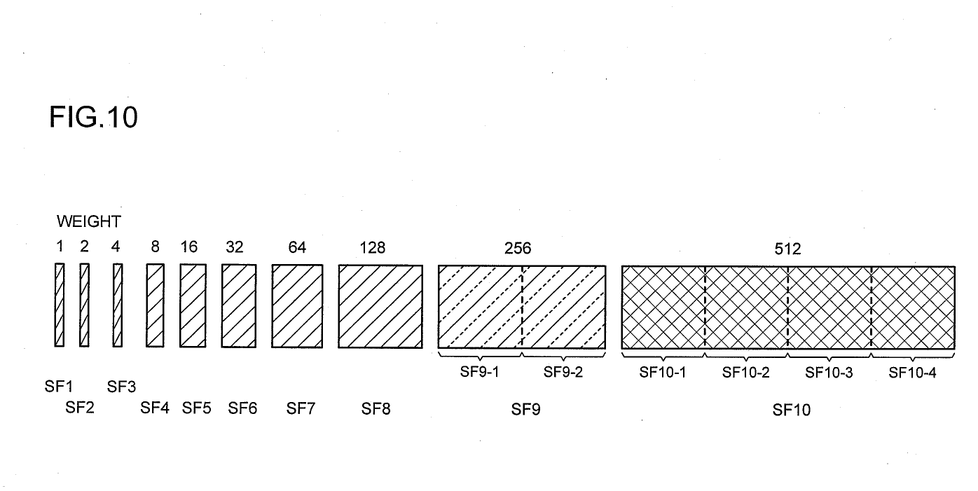

FIG. 10, which is similar to FIG. 4, shows an example of sub-frames driven for display by a sub-frame method according to the present embodiment. More specifically, one frame of an image signal is divided into 10 sub-frames (SF1 to SF10), and the display panel 11 is driven to display.

In more detail, each sub-frame is weighted based on the emission period. More specifically, the weight of each sub-frame is defined as SFn=2ⁿ⁻¹, that is, SF1:SF2:SF3:SF4:SF5:SF6:SF7:SF8:SF9:SF10=1:2:4:8:16:32:64:128:256:512. By a combination of such sub-frames, a 10-bit and 1024 grayscale display can be implemented.

Also, as in the case of Embodiment 1, the sub-frames SF9 and SF10 (weights are 256 and 512 respectively) are divided into two and four respectively, and divided sub-frames SF9-1 to SF9-2 and SF10-1 to SF10-4 are set. For example, each of the divided sub-frames SF9-1 to SF9-2 and SF10-1 to SF10-4 has an period equally corresponding to weight 128.

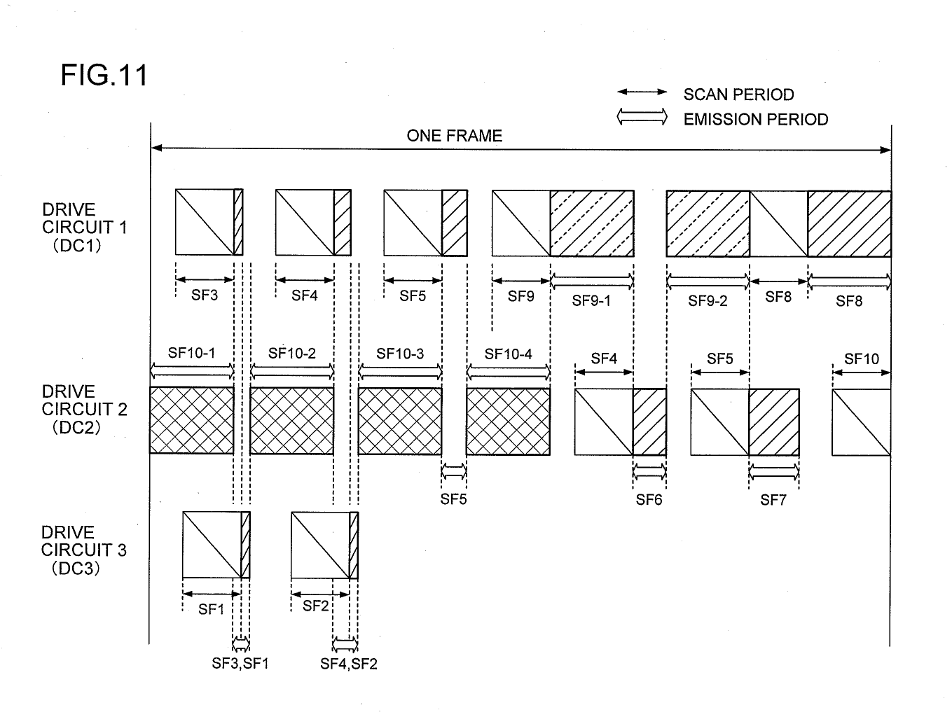

FIG. 11 is a diagram showing an example of a drive format when the above mentioned three drive circuits DC1, DC2 and DC3 are provided.

As the drive format in FIG. 11 shows, emission driving of the divided sub-frame SF10-1 is executed by the second drive circuit DC2 from the start point of one frame. The scan operation (data write) of the sub-frame SF10 has already been executed in the previous frame of this frame.

At the same time, with the emission driving of this divided sub-frame SF10-1, the scan operation (data write) of the sub-frame SF3 by the first drive circuit DC1 and the scan operation (date write) of the sub-frame SF1 by the third drive circuit DC3 are executed in parallel. After emission driving of the divided sub-frame SF10-1 ends, emission driving of the sub-frame SF3 is executed by the first drive circuit DC1. And after the emission driving of the sub-frame SF3, emission driving of the sub-frame SF1 is executed.

Then, emission driving of the divided sub-frame SF10-2 by the second drive circuit DC2, scan operation of the sub-frame SF4 by the first drive circuit DC1, and scan operation of the sub-frame SF2 by the third drive circuit DC3 are executed in parallel. After emission driving of the divided sub-frame SF10-2 ends, emission driving of the sub-frame SF2 is executed, and after the emission driving of the sub-frame SF2, emission driving of the sub-frame SF2 is executed.

Since the first, second and third drive circuits DC1, DC2 and DC3 are provided in each pixel as described above, while emission driving is being executed by one drive circuit, scan lines can be scanned and data write operation can be executed by the other two drive circuits simultaneously. According to the present embodiment, scan-count-per-frame can be further increased and the number of sub-frames can be increased, so and higher precision grayscale control can be implemented by increasing the number of grayscales.

In the above embodiments, the case of using an organic EL display was described as an example, but the present invention can be applied to any display of which ON/OFF can be switched at high-speed. For example, the present invention can also be applied to a ferroelectric liquid crystal display, plasma display and LED display.

### Embodiment 5

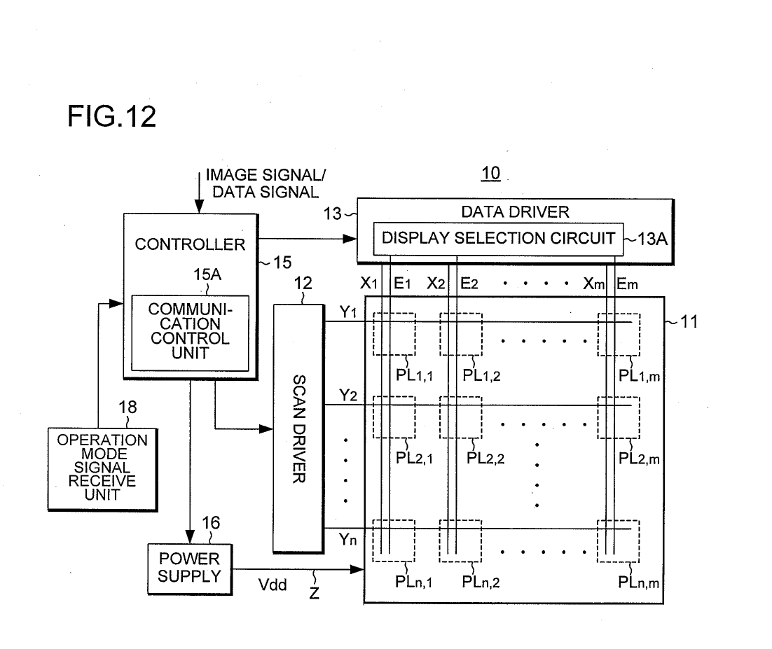

FIG. 12 is a block diagram showing a configuration of a display device 10 using an active matrix display panel according to Embodiment 5 of the present invention. In the present embodiment, the display device 10 is constructed as an image display/data transmission device which displays supplied image signals, and transmits two-dimensional data based on supplied data signals and communication mode specification signals.

This display device 10 has a display panel 11, scan driver 12, data driver 13, controller 15 and light emitting element drive power supply 16. In the data driver 13, a display selection circuit 13A, for selecting emission driving of a plurality of drive circuits provided in each pixel, is provided, as mentioned later. Also a communication control unit 15A for controlling communication when the data transmission mode is executed is provided in the controller 15. Furthermore an operation mode signal receive unit 18 is provided for receiving an operation mode specification signal to specify execution of an image signal display operation or a two-dimensional data transmission operation. The rest of the configuration is the same as the above mentioned embodiments.

When a transmission mode specification signal to specify execution of data transmission operation is received, the operation mode signal receive unit 18 sends the transmission mode specification signal to the controller 15. Responding to the transmission mode specification signal, the controller 15, along with the communication control unit 15A, controls the two-dimensional data display/transmission operation based on the received data signal. If the operation mode signal receive unit 18 does not receive the transmission mode specification signal, or if the image display mode specification signal to specify execution of image signal display operation is received, the controller 15 executes the image display control, as described in the above embodiments.

The communication control unit 15A controls communication according to a predetermined communication procedure. In other words, the communication control unit 15A constructs a two-dimensional data string based on the communication procedure and received data signals, and control communication according to a predetermined transmission (display) speed and a frame frequency (mentioned later).

A plurality of drive circuits provided in a pixel PL_{j,i} can be any drive circuit described in Embodiments 1 to 4. In the present embodiment, a case of providing two drive circuits DC1 and DC2, as shown in FIG. 7 of Embodiment 2, is described as an example.

In the data transmission mode, the display device 10 displays the data signal on the display panel 11 as an m×n bit two-dimensional data string (two-dimensional data pattern). By a receiving device (not illustrated) reading this display data string two-dimensionally, data transmission and data reception can be performed. Therefore, display of the two-dimensional data string by the display device 10 corresponds to data transmission, and in the present embodiment, display of the two-dimensional data string is called “data transmission”.

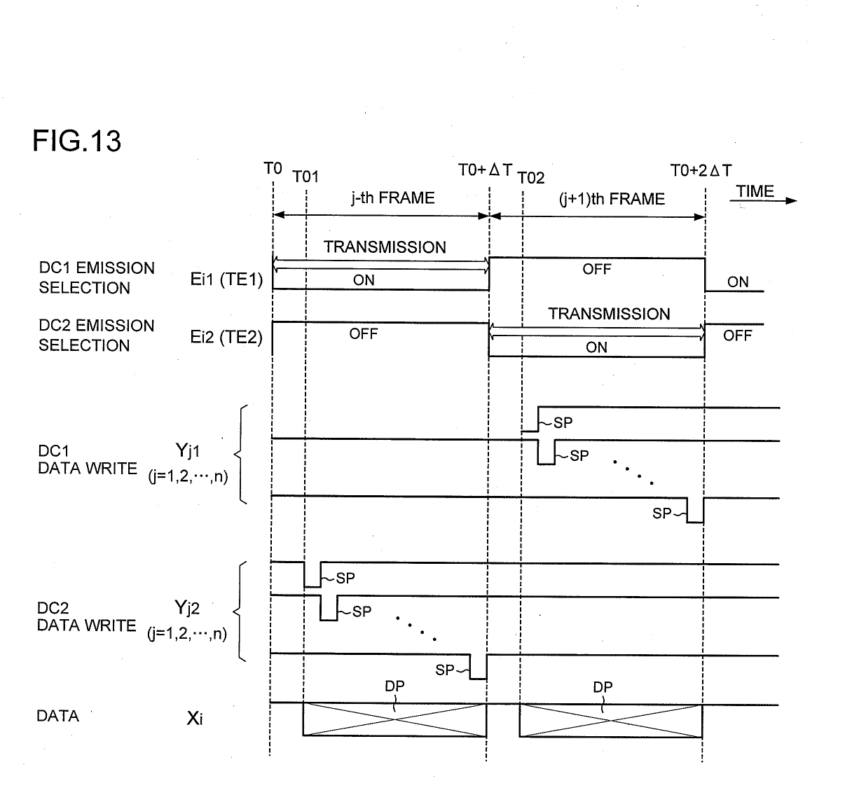

FIG. 13 is a timing chart showing the emission operation and scan (data write) operation by the drive circuits DC1 and DC2 according to the present embodiment, and the scan signal and data signal. In the present embodiment as well, a period for displaying and transmitting one two-dimensional data string (m×n two-dimensional data pattern) is called “one frame”, to make understanding easier. Hence, a different two-dimensional data string is set for each frame, and a switching frequency of the frames is called the “frame rate” or “frame frequency”.

According to FIG. 13, at the start time T0 of the j-th frame, selection voltage which indicates emission driving is supplied to the emission selection signal line Ei1, and the emission switching transistor TE1 of the first drive circuit DC1 is turned on. By this, data written in the first drive circuit DC1 (one frame data) is displayed on the display panel 11, and is read by the receiving device (not illustrated) two-dimensionally, whereby data transmission and data reception are executed. Data write to the first drive circuit DC1 is executed in the (j-1)th frame, which is a previous frame of this frame (j-th frame).

As FIG. 13 shows, one frame period is specified as ΔT. Therefore, the frame rate or frame frequency, which corresponds to the transmission speed of the two-dimensional data string (frame date), is defined as f=1/ΔT.

On the other hand, during the period of this frame (j-th frame), voltage to indicate non-emission driving (non-display) is supplied to the emission selection signal line Ei2 to the second drive circuit DC2, and the emission switching transistor TE2 of the drive circuit DC2 is maintained in turn-off state.

In the j-th frame period, the scan signal line Yj1 (j=1 to n) of the first drive circuit DC1 is maintained in the non-selection state, that is, the selection transistor TS1 is in turn-off state.

In the j-th frame period (e.g. period between time T01 to time T+ΔT), on the other hand, data is written (scanned) for the (j+1)th frame, which is the next frame, by the second drive circuit DC2, in parallel with the transmission (display) driving by the first drive circuit DC1. more specifically, a sequential scan signal SP is applied to the scan signal line Yj2 (j=1 to n) of the drive circuit DC2, and sequential line scanning is executed. Then corresponding to the sequential line scanning, a data signal DP, to indicate the emission brightness of each pixel, is applied via the data lines X1 to Xm, and data write is executed.

In the next frame (i.e., (j+1)th frame), data written in the second drive circuit DC2 (one frame data) in the j-th frame is sent to (displayed on) the display panel 11, which is opposite the case of the j-th frame. Meanwhile, simultaneous with the data transmission by the drive circuit DC2, write of the next two-dimensional data string (frame data) is executed in the first drive circuit DC1.

In this way, one frame data is transmitted by the two drive circuits DC1 and DC2 displaying data alternately for one frame at a time. In other words, while data transmission (display) is being executed by one drive circuit, data write is executed by the other drive circuit.

As mentioned above, if the drive circuit configuration shown in FIG. 7 is used, that is, if the emission switching transistors TE1 and TE2 of the two drive circuits DC1 and DC2 are transistors having opposite polarities (N-channel and P-channel), one transistor which turns on (display/transmission) and the other which turns off (data write) can be alternately set and executed by one selection switching signal Ei.

As described above, the display device 10 has both display (image display) function and two-dimensional data transmission function. The display device 10 can be constructed so as to operate at a higher frame frequency during data transmission than during display operation. As mentioned above, such an operation selection is performed by responding to the reception of the operation mode specification signal, to specify the image display operation or data transmission operation, by the operation mode signal receive unit 18 and controller 15.

In two-dimensional data transmission, the response speed of an optical element (e.g. liquid crystal, organic EL), which are in charge of the ON/Off of light output, and the data write speed of sequential line scanning, determine the upper limit of the data transfer speed. In the present embodiment, an organic EL, which excels in response characteristics, is used, and two drive circuits are provided for each pixel, therefore data is constantly written without loss of time, and display (transmission) is executed without delay, and as a result, display (transmission) of a two-dimensional data pattern can be switched at high-speed, and high-speed data transmission can be implemented.

The display device 10 according to the present invention can be used as a data transmission emission source of visible light communication. For the receive device, the speed of image sensing elements, such as CMOS, has increased remarkably, and high-speed communication can be implemented using the display device 10 and such a receive device as the light sensing element. For the display device 10, a light emitting element which emits light in a non-visible region may be used, instead of a light emitting element in a visible light region. For example, a light emitting element which emits light in an infrared region may be used.

As described above, the display device 10 has both display (image display) and two-dimensional data transmission functions. Therefore when a large volume of data is transmitted, the data transmission operation can be executed continuously, and data can be inserted between image display frames in one frame or in several frame units during the display (image display) operation.

The display 10 may have only two-dimensional data transmission functions, instead of having both display (image display) and two-dimensional data transmission functions. In this case, an operation mode signal receive unit 18 need not be provided.

### Embodiment 6

Embodiment 5 is a case in which two drive circuits DC1 and DC2 are provided in the pixel PL_{j,i}, but the present invention can also be applied to a case in which two or more drive circuits are provided in the pixel PL_{j,i}. For example, the present invention can also be applied to a case of the pixel PL_{j,i} further having the third drive circuit DC3, and can be comprised of a total of three drive circuits.

In the present embodiment, a case in which three drive circuits are provided in the pixel PL_{j,i} will be described, for example, as shown in FIG. 9.

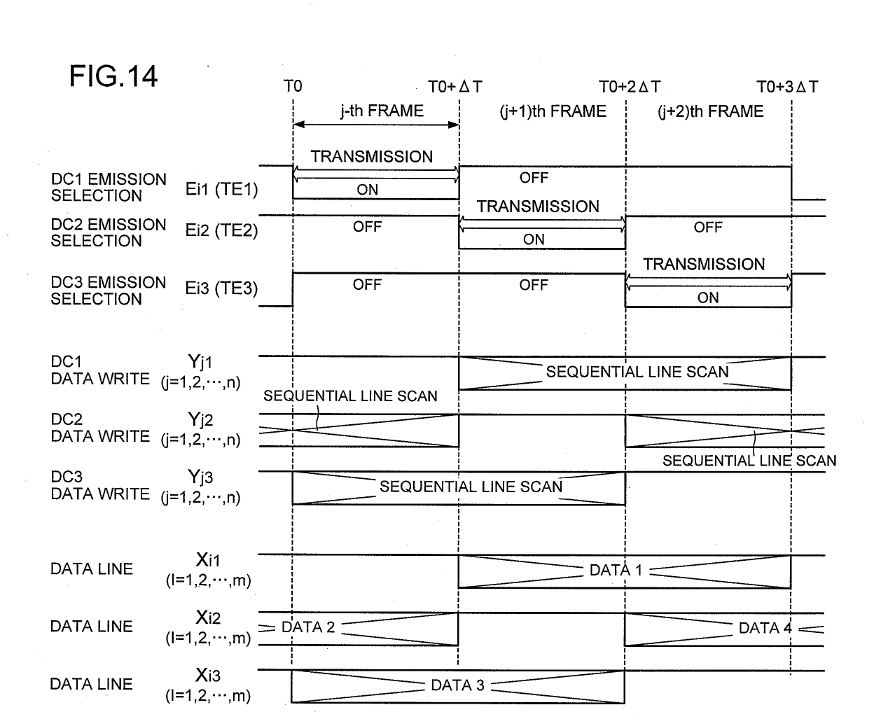

FIG. 14 is a timing chart showing the emission operation and scan (data write) operation by the first to third drive circuits DC1, DC2 and DC3 according to the present embodiment. In the present embodiment, the first to third drive circuits DC1, DC2 and DC3 are completely independently driven.

As FIG. 14 shows, one drive circuit always executes emission driving, and during this driving period, the two other drive circuits execute data write operation. For example, in the j-th frame, a selection voltage indicating emission driving is supplied to the emission selection signal line Ei1 of the first drive circuit DC1, and the emission switching transistor TE1 of the first drive circuit DC1 is turned on. Thereby the data (one frame data) written in the first drive circuit DC1 is displayed on the display panel 11, and data transmission is executed. Data write to the first drive circuit DC1 has already been executed in the previous frame of the frame (j-th frame).

On the other hand, during this frame (j-th frame), a voltage indicating non-emission driving (non-display) is supplied to the emission selection signal lines Ei2 and Ei3 of the second and third drive circuits DC2 and DC3, and the emission switching transistor TE2 of the drive circuits DC2 and DC3 is maintained in the turn-off state. During this frame period, data write is executed in the second and third drive circuits DC2 and DC3.

In the above mentioned Embodiment 5, the emission pattern switching speed (number of frames-per-unit-time) is limited by the emission data setting (write) time based on a sequential line (scanning). Whereas in the present embodiment, the number of emission fields-per-unit-time can be doubled, and data transmission speed can also be doubled, even if the scanning period in one frame is the same.

### Embodiment 7

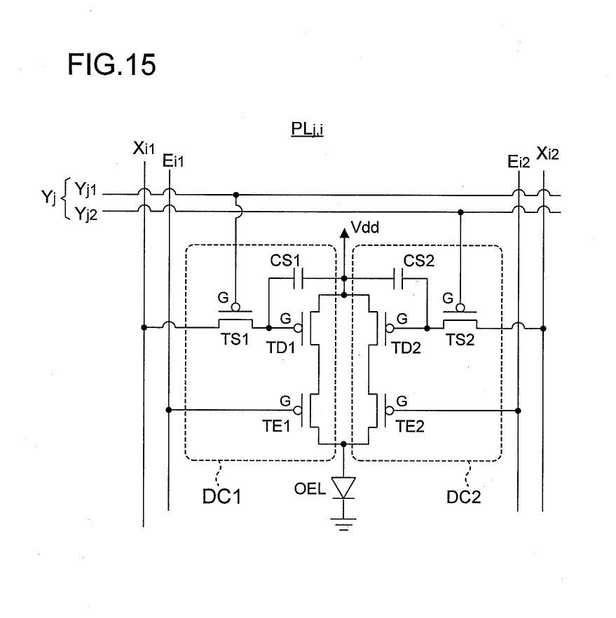

FIG. 15 is a diagram showing a configuration of a pixel PL_{j,i} according to Embodiment 7 of the present invention. Two drive circuits DC1 and DC2 are provided in the pixel PL_{j,i}, and two signal lines are provided for the scanning line Yj, emission selection line Ei and data line Xi respectively. More specifically, two signal lines (Yj1, Yj2) are provided for each of the scanning lines Yj, two signal lines (Ei1, Ei2) are provided for each of the emission selection lines Ei, and two signal lines (X11, Xi2) are provided for each of the data lines Xi.

Therefore, each drive circuit DC1 and DC2 can be independently controlled by each signal line, and the same kind of transistors can be used. In other words, all the transistors of the two drive circuits DC1 and DC2 can be P-channel transistors, for example, or all the transistors can be N-channel transistors. Hence, an advantage is that the manufacturing steps of the drive circuits can be simplified.

Since the two drive circuits can be controlled completely independently, the two circuits can execute data write simultaneously.

### Embodiment 8

In the above mentioned embodiments, a case of providing two or three drive circuits DC1, DC2 and DC3 in each pixel PL_{j,i} was described. However, at least four drive circuits DC1, DC2, DC3 DC4 . . . may be provided in each pixel PL_{j,i}.

The circuit configurations of each of the four or more drive circuits may be the same or different. However, it is preferable that each drive circuit is constructed such that each of at least the four drive circuits can be independently controlled, and the scanning line Yj, the emission selection line Ei and the data signal line Xi are connected to each drive circuit.

As an example of a case when each drive circuit has the same circuit configuration, two drive circuits DC1 and DC2 are provided (FIG. 15) in the Embodiment 7, for example, and independent scan signal lines (Yj1, Yj2) emission selection signal lines (Ei1, Ei2) and the data signal lines (Xi1, Xi2) are provided in each drive circuit, so that the drive circuits DC1 and DC2 can be independently controlled.

In Embodiment 4, three drive circuits DC1, DC2 and DC3 are provided (FIG. 9), the independent scan signal lines (Yj1, Yj2, Yj3), the emission selection signal lines (Ei1, Ei2, Ei3) and data signal lines (Xi1, Xi2, Xi3) are provided in each drive circuit, so that the drive circuits DC1, DC2 and DC3 can be independently controlled.

This configuration may be extended such that at least four drive circuits DC1, DC2, DC3, DC4 . . . are provided in each pixel PL_{j,i}. In this case as well, independent scan signal lines (Yj1, Yj2, Yj3, Yj4 . . . ), emission selection signal lines (Ei1, Ei2, Ei3, Ei4 . . . ), and data signal lines (Xi1, Xi2, Xi3, Xi4 . . . ) are provided so that each drive circuit can be independently controlled.

By this configuration, display driving and writing data signals (data write) of each pixel PL_{j,i} of the display panel 11 can be executed by independently controlling at least the four drive circuits.

As described above with various embodiments, according to the present invention, an active matrix driving type image display device, which can implement high brightness and high precision grayscale control, can be provided. A two-dimensional data display device which allows high-speed transmission can also be provided.

In the above embodiments, the configuration of pixel PL_{j,i} and the configuration of each drive circuit and scanning driver and the data driver and display selection circuit of each drive circuit provided in each pixel PL_{j,i} respectively can be applied to a case of the display device 10 being constructed as an image display device for displaying image signal, and a case of the display device 10 being constructed as a data transmission device for transmitting data signals as two-dimensional display data.

In the above embodiments, a case of using a display panel, which uses organic EL elements of which response speed is fast and with which high-speed switching is possible, was described, but any display panel in which ON/OFF switching is possible at high-speed can be used. For example, a ferroelectric liquid crystal display, inorganic EL display and LED display may be used instead. In the case of a display which displays data by driving a display element, which is a non-light emitting element, such as a liquid crystal display, “emission driving” is regarded as display driving, and “emission selection (circuit)” is regarded as display selection (circuit) in the above embodiments.

The above embodiments may be modified or combined. The numeric values used therein are merely examples. These values can be appropriately changed according to the device and elements to be used.

1. A display device that drives, based on a data signal, an active matrix display panel in which a display element is provided in each of a plurality of pixels and executes display, the display device comprising:
first and second drive circuits which are provided in each of the plurality of pixels, and connected to a scanning line and a data line of the display panel, to drive the display element;
a scan driver which sequentially scans each scanning line of the display panel;
a data driver which supplies the data signal to one of the first and second drive circuits via the data line according to the scanning by the scan driver, and writes the data signal in the one of the first and second drive circuits; and
a display controller which drives display elements based on data written in the other one of the drive circuits simultaneously with the data write by the data driver, and executes data display on the display panel, wherein
the data driver comprises a display drive selection circuit that generates a switching signal to indicate switching of a drive circuit that performs display driving from among the first and second drive circuits,
each of the first and second drive circuits comprises a capacitor that holds the data signal, a drive transistor that drives the display elements based on the held data signal, and a switching transistor that responds to the switching signal to drive the display elements based on the written data,
the display controller executes display control of the display panel based on a sub-frame grayscale method of dividing an image frame in the data signal into a plurality of sub-frames to perform grayscale display,
the display controller further divides at least one of the sub-frames into a plurality of divided sub-frames, and
the data driver, while executing display of one of the sub-frames and divided sub-frames, writes data corresponding to another one of the sub-frames and the divided sub-frame.

2-5. (canceled)

6. The display device according to claim 1, further comprising:
a transmission mode signal receive unit that specifies transmission operation of the data signal; and
a communication control unit that controls the data driver and the scan driver based on a frame rate in the transmission operation.

7. The display device according to claim 1, wherein:
each of the plurality of pixels has a third drive circuit, and
the display controller independently controls the first to third drive circuits to execute data display on the display panel and write the data signal.

8. The display device according to claim 1, wherein the display element is an organic electroluminescent (OEL) element.

9. The display device according to claim 1, wherein the display panel is a liquid crystal display.

10. The display device according to claim 1, wherein the display panel is an inorganic EL display.

11. The display device according to claim 1, wherein the display panel is an inorganic light emitting diode display.

12. The display device according to claim 1, wherein:
each of the plurality of pixels has at least four drive circuits, and
the display controller independently controls the at least four drive circuits, and executes data display on the display panel and writes the data signals.

13. A display device that drives, based on a data signal, an active matrix display panel in which a display element is provided in each of a plurality of pixels and executes display, the display device comprising:
first and second drive circuits which are provided in each of the plurality of pixels, and connected to a scanning line and a data line of the display panel, to drive the display element;
a scan driver which sequentially scans each scanning line of the display panel;
a data driver which supplies the data signal to one of the first and second drive circuits via the data line according to the scanning by the scan driver, and writes the data signal in the one of the first and second drive circuits; and
a display controller which drives display elements based on data written in the other one of the drive circuits simultaneously with the data write by the data driver, and executes data display on the display panel, wherein:
the data driver comprises a display drive selection circuit that generates a switching signal to indicate switching of a drive circuit that performs display driving from among the first and second drive circuits,
each of the first and second drive circuits comprises a capacitor that holds the data signal, a drive transistor that drives the display elements based on the held data signal, and a switching transistor that responds to the switching signal to drive the display elements based on the written data,
the display controller executes display control of the display panel based on a sub-frame grayscale method of dividing an image frame in the data signal into a plurality of sub-frames to perform grayscale display, and
the display controller further divides at least one of the sub-frames into a plurality of divided sub-frames, generates a drive format of the divided sub-frames and the sub-frames such that a duty ratio of the total display period of the divided sub-frames and the sub-frames to one frame period of the data signal becomes the maximum, and the data driver and the scan driver execute the data write and the data display based on the drive format.

14. The display device according to claim 13, further comprising:
a transmission mode signal receive unit that specifies transmission operation of the data signal; and
a communication control unit that controls the data driver and the scan driver based on a frame rate in the transmission operation.

15. The display device according to claim 13, wherein:
each of the plurality of pixels has a third drive circuit, and
the display controller independently controls the first to third drive circuits to execute data display on the display panel and write the data signal.

16. The display device according to claim 13, wherein the display element is an organic electroluminescent (OEL) element.

17. The display device according to claim 13, wherein the display panel is a liquid crystal display.

18. The display device according to claim 13, wherein the display panel is an inorganic EL display.

19. The display device according to claim 13, wherein the display panel is an inorganic light emitting diode display.

20. The display device according to claim 13, wherein:
each of the plurality of pixels has at least four drive circuits, and
the display controller independently controls the at least four drive circuits, and executes data display on the display panel and writes the data signals.
